(19) United States
(12) Patent Application Publication
(10) Pub. No.: US 2025/0108416 A1
(43) Pub. Date: Apr. 3, 2025

(54) ROTATION SPEED CALCULATION APPARATUS, ROTATION SPEED CALCULATION METHOD, SUBSTRATE CLEANING APPARATUS, AND SUBSTRATE PROCESSING APPARATUS

(71) Applicant: EBARA CORPORATION, Tokyo (JP)

(72) Inventors: Fuyuki OGAKI, Tokyo (JP); Yusuke WATANABE, Tokyo (JP); Michiaki MATSUDA, Tokyo (JP); Kohei WAKUI, Tokyo (JP); Kiyoshi SUZUKI, Tokyo (JP)

(21) Appl. No.: 18/895,237

(22) Filed: Sep. 24, 2024

(30) Foreign Application Priority Data
Sep. 28, 2023 (JP) 2023-168333

(51) Int. Cl. B08B 13/00; B08B 1/34; B24B 37/34

(52) U.S. Cl. CPC B08B 13/00; B08B 1/34; B24B 37/34

(57) ABSTRACT

Provided is a rotation speed calculation apparatus including: a first vibration sensor configured to detect a vibration generated when a notch in a peripheral edge portion of a substrate to be cleaned hits a roller holding the peripheral edge portion of the substrate when the substrate is rotated by driving the roller to rotate; a second vibration sensor configured to detect a vibration of a housing defining a space in which the substrate is cleaned; and a rotation speed calculator configured to calculate a rotation speed of the substrate based on the vibration detected by the first vibration sensor and the vibration detected by the second vibration sensor.

### CROSS-REFERENCE TO RELATED APPLICATIONS

This application claims the benefit of Japanese Priority Patent Application JP 2023-168333 filed on Sep. 28, 2023, the entire contents of which are incorporated herein by reference.

### FIELD

The present disclosure relates to a rotation speed calculation apparatus and a rotation speed calculation method for calculating a rotation speed of a substrate, a substrate cleaning apparatus, and a substrate processing apparatus.

### BACKGROUND

For a substrate cleaning apparatus, there has been known a technique in which a rotation speed of a substrate is calculated by detecting vibrations or sounds generated when a notch in a peripheral edge portion of the substrate hits a roller (JP 7078602 B2). However, the detected vibrations or sounds include not only vibrations (signal) generated when the notch hits the roller but also vibrations (noise) generated by other factors.

### SUMMARY

By way of example, the following aspects are provided.

[1] A rotation speed calculation apparatus comprising:
a first vibration sensor configured to detect a vibration generated when a notch in a peripheral edge portion of a substrate to be cleaned hits a roller holding the peripheral edge portion of the substrate when the substrate is rotated by driving the roller to rotate;
a second vibration sensor configured to detect a vibration of a housing defining a space in which the substrate is cleaned; and
a rotation speed calculator configured to calculate a rotation speed of the substrate based on the vibration detected by the first vibration sensor and the vibration detected by the second vibration sensor.
   [2] The rotation speed calculation apparatus according to [1], wherein the rotation speed calculator calculates the rotation speed of the substrate based on the vibrations detected by the first vibration sensor and the second vibration sensor so as to cancel the vibration of the housing.
   [3] The rotation speed calculation apparatus according to [1], wherein the rotation speed calculator calculates the rotation speed of the substrate based on a value obtained by subtracting the vibration detected by the second vibration sensor from the vibration detected by the first vibration sensor.
   [4] A rotation speed calculation apparatus comprising:
two or more vibration sensors configured to detect vibrations generated when a notch in a peripheral edge portion of a substrate to be cleaned hits a plurality of rollers holding the peripheral edge portion of the substrate, respectively, when the substrate is rotated by driving the rollers to rotate, each of the two or more vibration sensors being provided to correspond to each of two or more of the plurality of rollers; and
a rotation speed calculator configured to calculate a rotation speed of the substrate based on the vibrations detected by the two or more vibration sensors.
   [5] The rotation speed calculation apparatus according to [4], wherein the rotation speed calculator calculates the rotation speed of the substrate based on a value obtained by adding the vibrations detected by the two or more vibration sensors.
   [6] The rotation speed calculation apparatus according to [4] or [5], wherein a first number of rollers is equal to a second number of vibration sensors, and
each of the two or more vibration sensors is provided to correspond to each of the plurality of rollers.
   [7] A rotation speed calculation apparatus comprising:
a first sound sensor configured to detect a sound generated when a notch in a peripheral edge portion of a substrate to be cleaned hits a roller holding the peripheral edge portion of the substrate when the substrate is rotated by driving the roller to rotate;
a second sound sensor configured to detect a sound generated from a housing defining a space in which the substrate is cleaned; and
a rotation speed calculator configured to calculate a rotation speed of the substrate based on the sound detected by the first sound sensor and the sound detected by the second sound sensor.
   [8] A rotation speed calculation apparatus comprising:
two or more sound sensors configured to detect sounds generated when a notch in a peripheral edge portion of a substrate to be cleaned hits a plurality of rollers holding the peripheral edge portion of the substrate, respectively, when the substrate is rotated by driving the rollers to rotate, each of the two or more sound sensors being provided to correspond to each of two or more of the plurality of rollers; and
a rotation speed calculator configured to calculate a rotation speed of the substrate based on the sounds detected by the two or more sound sensors.
   [9] A substrate cleaning apparatus comprising:
a roller;
a rotation driver configured to rotate a substrate to be cleaned by driving the roller to rotate;
a substrate cleaning tool configured to perform cleaning in contact with the substrate that is being rotated; and
the rotation speed calculation apparatus according to any one of [1] to [9].
   [10] A substrate processing apparatus comprising:
a substrate polishing apparatus configured to polish a substrate; and
the substrate cleaning apparatus according to [9] configured to clean the polished substrate.
   [11] A rotation speed calculation method comprising:
a first step of rotating a substrate to be cleaned by driving a roller holding a peripheral edge portion of the substrate to rotate;
a second step of detecting, by a first vibration sensor, a vibration generated when a notch in the peripheral edge portion of the substrate hits the roller;
a third step of detecting, by a second vibration sensor, a vibration of a housing defining a space in which the substrate is cleaned; and
a fourth step of calculating a rotation speed of the substrate based on the vibration detected by the first vibration sensor and the vibration detected by the second vibration sensor.
   [12] A rotation speed calculation method comprising:
a first step of rotating a substrate to be cleaned by driving a plurality of rollers holding a peripheral edge portion of the substrate to rotate;
a second step of detecting, by two or more vibration sensors, vibrations generated when a notch in the peripheral edge portion of the substrate hits the plurality of rollers, respectively; and
a third step of calculating a rotation speed of the substrate based on the vibrations detected by the two or more vibration sensors.
   [13] A rotation speed calculation method comprising:
a first step of rotating a substrate to be cleaned by driving a roller holding a peripheral edge portion of the substrate to rotate;
a second step of detecting, by a first sound sensor, a sound generated when a notch in the peripheral edge portion of the substrate hits the roller;
a third step of detecting, by a second sound sensor, a sound generated from a housing defining a space in which the substrate is cleaned; and
a fourth step of calculating a rotation speed of the substrate based on the sound detected by the first sound sensor and the sound detected by the second sound sensor.
   [14] A rotation speed calculation method comprising:
a first step of rotating a substrate to be cleaned by driving a plurality of rollers holding a peripheral edge portion of the substrate to rotate;
a second step of detecting, by two or more sound sensors, sounds generated when a notch in the peripheral edge portion of the substrate hits the plurality of rollers, respectively; and
a fourth step of calculating a rotation speed of the substrate based on the sounds detected by the two or more sound sensors.

### BRIEF DESCRIPTION OF DRAWINGS

FIG. 1 is a schematic configuration diagram of a substrate processing apparatus 100 according to an embodiment;

FIG. 2 is a schematic diagram of a substrate cleaning apparatus 4 according to a first embodiment;

FIG. 3 is a plan view illustrating how rollers 42a to 42d and rotation drivers 43a and 43b are arranged;

FIG. 4 is a diagram for explaining a notch formed in a substrate W;

FIG. 5 is a diagram for explaining a rotation speed calculation method according to the first embodiment;

FIG. 6 is a schematic diagram of a substrate cleaning apparatus 4 according to a second embodiment;

FIG. 7A is a diagram for explaining a rotation speed calculation method according to a second embodiment; and

FIG. 7B is a diagram for explaining the rotation speed calculation method according to the second embodiment.

### DETAILED DESCRIPTION OF EMBODIMENTS

Hereinafter, embodiments according to the present invention will be specifically described with reference to the drawings.

### First Embodiment

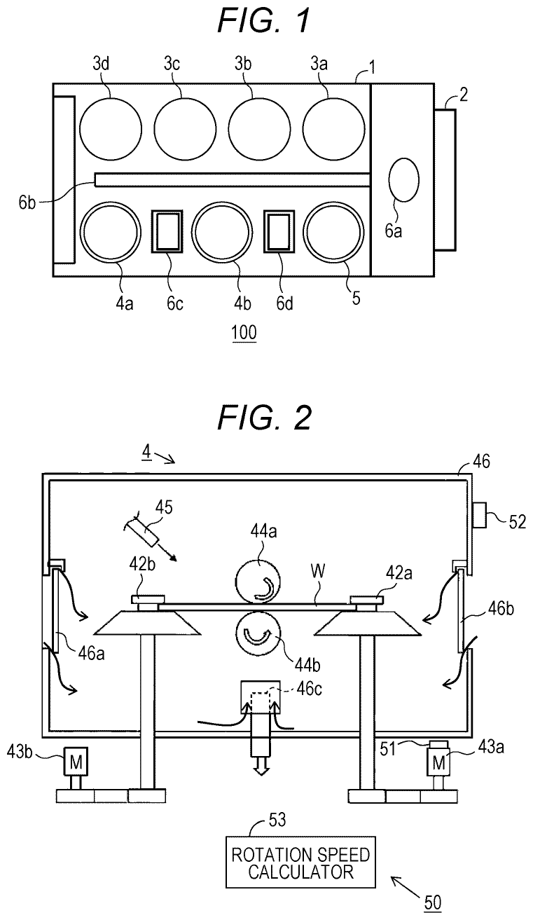

FIG. 1 is a schematic configuration diagram of a substrate processing apparatus 100 according to an embodiment. The substrate processing apparatus 100 is, for example, a CMP apparatus, and includes a substantially rectangular housing 1 and a load port 2 disposed adjacent to the housing 1.

A substrate cassette (not illustrated) for stocking a plurality of substrates W is placed on the load port 2. Examples of the substrate W include a semiconductor wafer. However, the substrate W to be processed is not limited to a semiconductor wafer, and may be another type of substrate used for manufacturing a semiconductor device such as a glass substrate or a ceramic substrate. In addition, a semiconductor film, a metal film, or the like is formed on at least one surface of the substrate W.

The substrate processing apparatus 100 includes one or more (four in FIG. 1) substrate polishing apparatuses 3a to 3d (when not particularly distinguished from each other, they may be collectively referred to as the “substrate polishing apparatus 3”), one or more (two in FIG. 1) substrate cleaning apparatuses 4a and 4b (when not particularly distinguished from each other, they may be collectively referred to as the “substrate cleaning apparatus 4”), and one or more (one in FIG. 1) substrate drying apparatuses 5, which are disposed inside the housing 1.

As an example, the substrate polishing apparatuses 3a to 3d are disposed along one side of the housing 1 in the longitudinal direction. The substrate cleaning apparatuses 4a and 4b and the substrate drying apparatus 5 are disposed along the other side of the housing 1 in the longitudinal direction.

The substrate polishing apparatus 3 polishes the surface of the substrate W. More specifically, the substrate polishing apparatus 3 supplies slurry onto the substrate W while rotating the substrate W, and polishes the surface of the substrate W by pressing a polishing member (not illustrated) against the surface of the substrate W. Polishing debris or slurry may remain on the polished substrate W.

The substrate cleaning apparatus 4 cleans the surface of the polished substrate W. More specifically, the substrate cleaning apparatus 4 cleans the surface of the substrate W by pressing a substrate cleaning tool (not illustrated in FIG. 1) against the surface of the substrate W while rotating the substrate W. A specific example of the substrate cleaning apparatus 4 will be described later.

The substrate drying apparatus 5 dries the surface of the cleaned substrate W. For example, the substrate drying apparatus 5, which is a spin drying device, ejects isopropyl alcohol vapor from an injection nozzle to the rotating substrate W to dry the substrate W, while rotating the substrate W at a high speed using a centrifugal force to dry the substrate W.

In addition, the substrate processing apparatus 100 includes substrate transport apparatuses 6a to 6d (when not particularly distinguished from each other, they may be collectively referred to as the “substrate transport apparatus 6”), which are disposed inside the housing 1.

The substrate transport apparatus 6a is disposed adjacent to the load port 2. The substrate transport apparatus 6a receives the substrate W before being processed from the load port 2 and transfers the substrate W to the substrate transport apparatus 6b, or receives the substrate W after being processed from the substrate transport apparatus 6b.

The substrate transport apparatus 6b extends in the longitudinal direction at a central portion of the housing 1. The substrate transport apparatus 6b receives the substrate W before being processed from the substrate transport apparatus 6a and transports the substrate W to one of the substrate polishing apparatuses 3a to 3d, receives the substrate W after being polished from the substrate polishing apparatuses 3a to 3d and transfers the substrate W to the substrate transport apparatus 6c, or receives the substrate W after being dried from the substrate transport apparatus 6d and transfers the substrate W to the substrate transport apparatus 6a.

The substrate transport apparatus 6c is disposed between the substrate cleaning apparatuses 4a and 4b. The substrate transport apparatus 6c receives the polished substrate W from the substrate transport apparatus 6b and transports the substrate W to either the substrate cleaning apparatus 4a or 4b, or receives the cleaned substrate W from the substrate cleaning apparatus 4a and transports the substrate W to the substrate cleaning apparatus 4b.

The substrate transport apparatus 6d is disposed between the substrate cleaning apparatus 4b and the substrate drying apparatus 5. The substrate transport apparatus 6d receives the cleaned substrate W from the substrate cleaning apparatus 4b and transports the substrate W to the substrate drying apparatus 5, or receives the dried substrate W from the substrate drying apparatus 5 and transfers the substrate W to the substrate transport apparatus 6b.

Note that the arrangement of the substrate polishing apparatus 3, the substrate cleaning apparatus 4, the substrate drying apparatus 5, and the substrate transport apparatus 6 is merely an example. It is only required to provide one or more substrate transport apparatuses 6 capable of transporting the substrate W through the substrate polishing apparatus 3, the substrate cleaning apparatus 4, and the substrate drying apparatus 5 in this order.

FIG. 2 is a schematic view of the substrate cleaning apparatus 4 according to the first embodiment. The substrate cleaning apparatus 4 includes one or more (four in the present embodiment) rollers 42a to 42d (only the rollers 42a and 42b are illustrated in FIG. 2), rotation drivers 43a and 43b, substrate cleaning tools 44a and 44b, a cleaning liquid supply nozzle 45, and a housing 46.

The rollers 42a to 42d hold a peripheral edge portion of the substrate W. The rotation drivers 43a and 43b drive the rollers 42a to 42d to rotate, thereby rotating the substrate W.

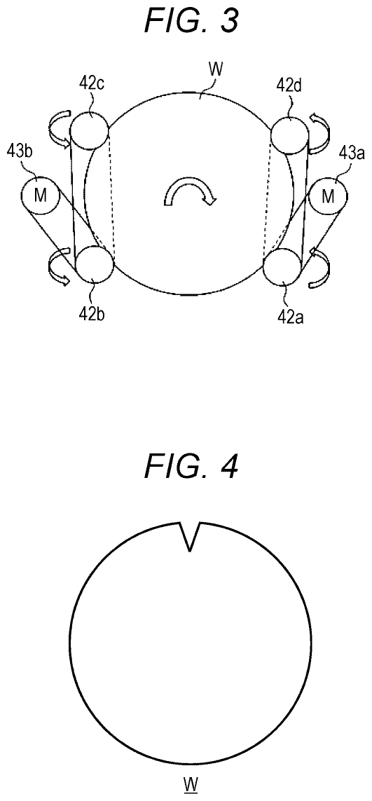

FIG. 3 is a plan view illustrating how the rollers 42a to 42d and the rotation drivers 43a and 43b are arranged. The rollers 42a to 42d are arranged at equal intervals clockwise in this order. For example, the rollers 42b and 42d are disposed adjacent to the roller 42a, and the roller 42c is disposed opposite to the roller 42a.

The rotation drivers 43a and 43b include motors (not illustrated). As illustrated in FIG. 3, the motor of the rotation driver 43a drives the rollers 42a and 42d to rotate via a pulley and a belt. Also, the motor of the rotation driver 43b drives the rollers 42b and 42c to rotate via a pulley and a belt. The rotation drivers 43a and 43b drive the rollers 42a to 42d to rotate in the same direction (counterclockwise in the example illustrated in FIG. 3). As a result, the substrate W held by the rollers 42a to 42d is rotated in a direction opposite to the rotation direction of the rollers 42a to 42d (clockwise in the example illustrated in FIG. 3) by a frictional force acting between each of the rollers 42a to 42d and the peripheral edge portion of the substrate W.

In the peripheral edge portion of the substrate W according to the present embodiment, a notch (formed by cutting out a partial portion of the substrate W in a V shape) as illustrated in FIG. 4 is formed. Therefore, when the substrate W rotates and the notch hits the rollers 42a to 42d, a vibration or a sound is generated. When the rotation speed (the number of rotations per unit time) of the substrate W is constant, a vibration or a sound is generated at a cycle. Therefore, the rotation speed can be calculated from the cycle.

Returning to FIG. 2, the substrate cleaning tools 44a and 44b contact the upper and lower surfaces of the substrate W, respectively, to clean the substrate W. The substrate cleaning tools 44a and 44b illustrated in FIG. 2 have an elongated columnar shape, and are roll substrate cleaning tools (roll sponges) made of, for example, polyvinyl alcohol (PVA). However, the substrate cleaning tools 44a and 44b do not need to be roll cleaning tools, and may be, for example, columnar pen-type cleaning tools extending in the vertical direction, or buff cleaning/polishing members each having a rotation axis extending in the vertical direction.

The cleaning liquid supply nozzle 45 supplies a cleaning liquid to the upper surface of the substrate W. The cleaning liquid may be pure water, a chemical liquid, or the like. Also, a cleaning liquid supply nozzle for supplying a cleaning liquid to the lower surface of the substrate W may be provided.

The housing 46 defines a cleaning space for cleaning the substrate W. The housing 46 houses at least the rollers 42a to 42d, the substrate cleaning tools 44a and 44b, and the cleaning liquid supply nozzle 45, and may further house the rotation drivers 43a and 43b. By arranging the rollers 42a to 42d, the substrate cleaning tools 44a and 44b, and the cleaning liquid supply nozzle 45 inside the housing 46, the cleaning liquid supplied onto the substrate W is prevented from scattering to the outside of the cleaning space.

Openings (substrate loading and unloading ports) for loading and unloading the substrate W are formed in the side walls of the housing 46, and the substrate loading and unloading ports can be opened and closed by shutters 46a and 46b. In addition, an exhaust port 46c is formed in the bottom of the housing 46. Air inside the housing 46 is discharged from the exhaust port 46c, and air outside the housing 46 flows in through gaps between the substrate loading and unloading ports and the shutters 46a and 46b, thereby ventilating the cleaning space.

As one of the features of the present embodiment, the substrate cleaning apparatus 4 is provided with a rotation speed calculation apparatus 50. The rotation speed calculation apparatus 50 may be included in the substrate cleaning apparatus 4, or may be separate from the substrate cleaning apparatus 4. The rotation speed calculation apparatus 50 includes vibration sensors 51 and 52 and a rotation speed calculator 53.

The vibration sensor 51 detects a vibration generated when the notch of the substrate W hits the rollers 42a to 42d during the cleaning of the substrate. Specifically, the vibration sensor 51 is provided to correspond to one (the roller 42a in the example of FIG. 2) of the rollers 42a to 42d, and mainly detects a vibration generated when the notch of the substrate W hits the roller 42a. Note that although the installation position of the vibration sensor 51 is not particularly limited, the vibration sensor 51 is installed, for example, on the motor as illustrated in FIG. 2. However, the vibration sensor 51 detects not only a vibration generated when the notch of the substrate W hits the roller 42a but also vibrations generated by other factors (particular vibration of the housing 46 as will be described later).

The vibration sensor 52 mainly detects a vibration of the housing 46. Although the installation position of the vibration sensor 52 is not particularly limited, the vibration sensor 52 is, for example, attached to the inside or the outside of the housing 46.

The rotation speed calculator 53 calculates a rotation speed of the substrate W based on the vibration detected by the vibration sensors 51 and 52.

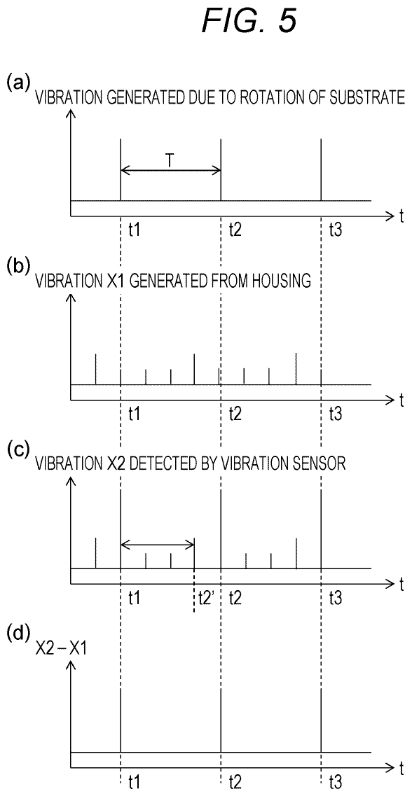

FIG. 5 is a diagram for explaining a rotation speed calculation method according to the first embodiment.

FIG. 5(a) schematically illustrates a vibration generated when the substrate W rotates and the notch hits the roller 42a. When the rotation speed of the substrate W is constant, a large vibration is generated at a regular cycle T. In the illustrated example, a large vibration is generated at times t1, t2, and t3. Therefore, a rotation speed can be calculated from differences in time at which a large vibration is generated (e.g., t2−t1 and t3−t2). Alternatively, a rotation speed can be calculated from the number of times a large vibration is generated per unit time.

However, it is difficult for the vibration sensor 51 to detect only the vibration illustrated in FIG. 5(a). This is because, in the substrate cleaning apparatus 4, a vibration is generated in addition the vibration generated when the notch hits the roller 42a. Examples of such a vibration include a vibration from the housing 46.

FIG. 5(b) schematically illustrates a vibration generated from the housing 46. The housing 46 causes vibrations due to various factors. These vibrations include vibrations unrelated to the rotation of the substrate W. A vibration X1 may be cyclical, or may not be cyclical. The vibration sensor 52 detects such a vibration generated from the housing 46. It can also be said that FIG. 5(b) illustrates the vibration X1 detected by the vibration sensor 52. The vibration X1 is noise in the calculation of the rotation speed.

FIG. 5(c) schematically illustrates a vibration X2 detected by the vibration sensor 51. The vibration sensor 51 mainly detects a vibration generated when the notch of the substrate W hits the roller 42a, but also detects other vibrations. As for the other vibrations, large vibrations are generated particularly from the housing 46. Therefore, the vibration X2 detected by the vibration sensor 51 is a combination of the vibration generated when the notch of the substrate W hits the roller 42a (FIG. 5(a)) and the vibration generated from the housing 46 (FIG. 5(b)).

If the rotation speed calculator 53 tries to calculate a rotation speed only from the vibration X2 detected by the vibration sensor 51, for example, a time t1-t2′ in FIG. 5(c) may be erroneously recognized as a rotation cycle, and a rotation speed may be calculated erroneously.

Therefore, the rotation speed calculator 53 according to the present embodiment calculates a rotation speed of the substrate W by canceling the vibration of the housing 46 in consideration of not only the vibration X2 detected by the vibration sensor 51 but also the vibration X1 detected by the vibration sensor 52.

As a specific processing example, the rotation speed calculator 53 subtracts the vibration X1 detected by the vibration sensor 52 from the vibration X2 detected by the vibration sensor 51. As a result, as illustrated in FIG. 5(d), the vibration of the housing 46 is canceled, and a value (signal) corresponding to the vibration mainly generated when the notch hits the roller 42a is obtained. In this signal, a large value is generated at a cycle T corresponding to the notch hitting the roller 42a.

Then, the rotation speed calculator 53 calculates a rotation speed of the substrate W based on the signal value. For example, the rotation speed calculator 53 can calculate a rotation speed of the substrate W from the cycle T at which the signal illustrated in FIG. 5(d) is equal to or more than a predetermined value. Alternatively, the rotation speed calculator 53 can calculate a rotation speed of the substrate W from the number of times per unit time at which the signal illustrated in FIG. 5(d) is equal to or more than a predetermined value.

In this manner, according to the first embodiment, a rotation speed is calculated by subtracting the vibration of the housing 46. Therefore, even if the vibration from the housing 46 becomes noise, the influence of the noise can be suppressed and the rotation speed calculation accuracy can be improved.

Note that sound sensors (e.g., microphones) may be used instead of the vibration sensors 51 and 52. The sound sensor replacing the vibration sensor 51 detects sound generated when the notch hits the roller. The sound sensor replacing the vibration sensor 52 is provided, for example, on the housing 46 to detect sound generated from the housing.

### Second Embodiment

In a second embodiment to be described next, a vibration sensor is provided in each of the rollers 42a to 42d. Hereinafter, the description of the points in common with the first embodiment will be omitted or simplified, and differences will be mainly described. In the present embodiment, in order to simplify the description, it is assumed that the rollers 42a to 42d are arranged at equal intervals without considering a vibration generated in the housing 46.

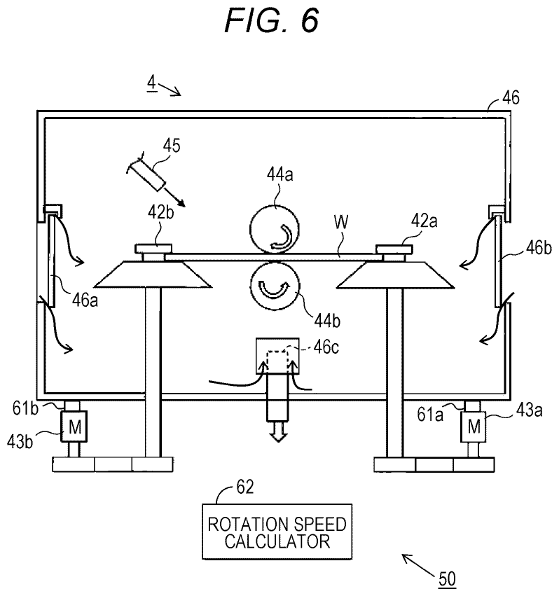

FIG. 6 is a schematic view of a substrate cleaning apparatus 4 according to the second embodiment. A rotation speed calculation apparatus 50 provided in the substrate cleaning apparatus 4 includes vibration sensors 61a to 61d (only the vibration sensors 61a and 61b shown in FIG. 6) and a rotation speed calculator 62. The vibration sensors 61a to 61d are provided to correspond to the rollers 42a to 42d, respectively. The vibration sensors 61a to 61d are installed, for example, on motors corresponding to the respective rollers. The vibration sensors 61a to 61d mainly detect vibrations generated when the notch of the substrate W hits the rollers 42a to 42d.

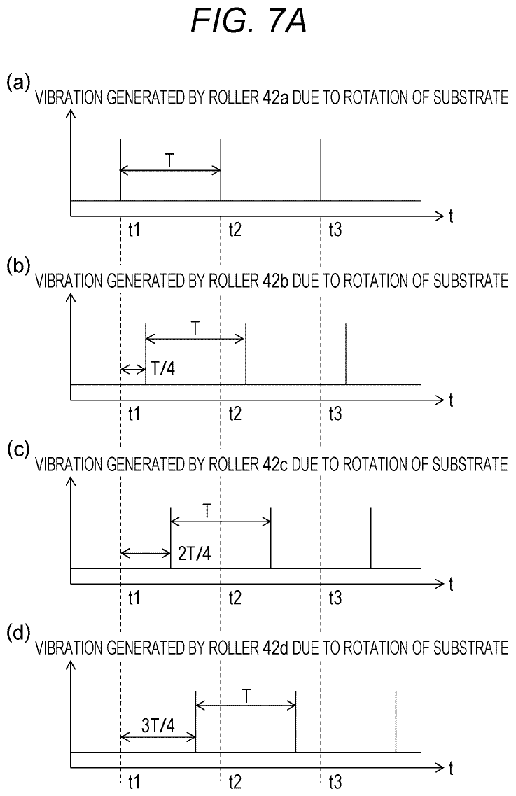

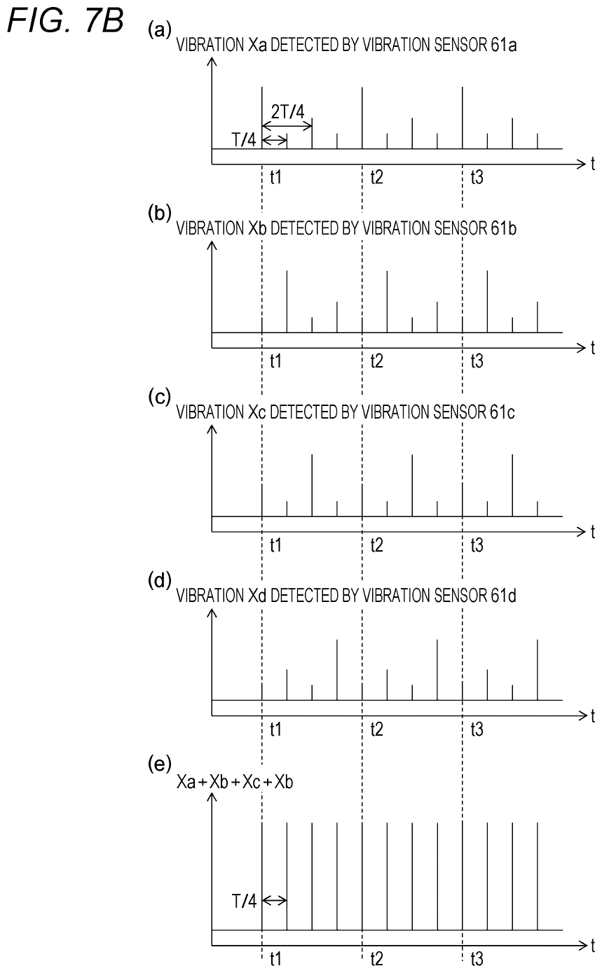

FIGS. 7A and 7B are diagrams for explaining a rotation speed calculation method according to the second embodiment.

FIGS. 7A(a) to 7A(d) schematically illustrate vibrations generated when the notch hits the rollers 42a to 42d, respectively. The cycle of vibration generated by each of the rollers 42a to 42d is a constant value T corresponding to the rotation speed of the substrate W, but the phases are shifted by T/4 (in a case where the rollers 42a to 42d are not arranged at equal intervals, the phases are shifted according to the arrangement intervals).

FIGS. 7B(a) to 7B(d) schematically illustrate vibrations Xa to Xd detected by the vibration sensors 61a to 61d, respectively.

As illustrated in FIG. 7B(a), the vibration sensor 61a corresponding to the roller 42a detects vibrations generated when the notch hits the roller 42a at times t1, t2, and t3. Since these vibrations are generated by the roller 42a corresponding to the vibration sensor 61a, the detected vibrations are relatively large. However, it is not necessarily large enough to calculate a rotation speed.

The vibration sensor 61a detects vibrations generated when the notch hits the roller 42b at times t1+T/4, t2+T/4, and t3+T/4. Since these vibrations are generated by the roller 42b adjacent to the roller 42a corresponding to the vibration sensor 61a, the detected vibrations are relatively small.

The vibration sensor 61a detects vibrations generated when the notch hits the roller 42c at times t1+2T/4, t2+2T/4, and t3+2T/4. Since these vibrations are generated by the roller 42c opposite to the roller 42a corresponding to the vibration sensor 61a, the detected vibrations are smaller than the vibrations detected at the times t1 and the like, but are larger than the vibrations detected at the times t1+T/4 and the like.

The vibration sensor 61a detects vibrations generated when the notch hits the roller 42d at times t1+3T/4, t2+3T/4, and t3+3T/4. Since these vibrations are generated by the roller 42d adjacent to the roller 42a corresponding to the vibration sensor 61a, the detected vibrations are substantially equal to the vibrations detected at the times t1+T/4 and the like.

The vibrations Xb to Xd (FIGS. 7B(b) to 7B(d)) detected by the vibration sensors 61b to 61d are shifted in phase by T/4 from the vibration X1 detected by the vibration sensor 61a.

The rotation speed calculator 62 according to the present embodiment calculates a rotation speed of the substrate W based on the vibrations Xa to Xd detected by the vibration sensors 61a to 61d. Specifically, the rotation speed calculator 62 adds vibrations Xa to Xd. As a result, as illustrated in FIG. 7B(e), a value (signal) corresponding to the vibration generated when the notch hits each of the rollers 42a to 42d is obtained. In this signal, a large value is generated at a cycle T/4 corresponding to the notch hitting each of the rollers 42a to 42d. Even if the vibration generated when the notch hits each of the rollers 42a to 42d is not sufficiently large, a signal value corresponding to the vibrations generated when the notch hits the rollers 42a to 42d, respectively, becomes sufficiently large by adding the vibrations.

Then, the rotation speed calculator 62 calculates a rotation speed of the substrate W based on the signal value. For example, the rotation speed calculator 62 can calculate a rotation speed of the substrate W from the cycle T/4 at which the signal illustrated in FIG. 7B(e) is equal to or more than a predetermined value. Alternatively, the rotation speed calculator 62 can calculate a rotation speed of the substrate W from the number of times per unit time at which the signal illustrated in FIG. 7B(e) is equal to or more than a predetermined value.

In this manner, according to the second embodiment, the vibrations generated by the rollers 42a to 42d are added. Therefore, even if the vibration generated by each of the rollers 42a to 42d is not sufficiently large, the rotation speed calculation accuracy can be improved.

The vibration sensors 61a to 61d may be provided to correspond to all the rollers 42a to 42d, respectively, or the vibration sensors 61a and 61c may be provided only on some of the rollers (e.g., the rollers 42a and 42c opposite to each other).

Instead of the vibration sensors 61a to 61d, sound sensors (e.g., microphones) that detects sounds generated when the notch hits the rollers may be used.

As described above, according to the present disclosure, since it is not necessary to use an idler pulley to calculate a rotation speed, the number of components can be reduced, and the substrate W is not contaminated by the idler pulley. Further, even if vibrations or sounds generated when the notch hits the rollers are small, a rotation speed can be accurately calculated.

Some or all of the functional units described in the present specification may be realized by a program. The program referred to in the present specification may be distributed in a non-temporarily recorded state in a computer-readable recording medium, may be distributed via a communication line (including wireless communication) such as the Internet, or may be distributed in an installed state in any terminal.

Based on the above description, a person skilled in the art may conceive additional effects and various modifications of the present invention, and aspects of the present invention are not limited to the several embodiments described above. For example, an invention made by extracting only a part of each embodiment or an invention made by combining a plurality of embodiments is naturally assumed. Various additions, modifications, and partial deletions can be made without departing from the conceptual idea and spirit of the present invention derived from the contents defined in the claims and equivalents thereof.

For example, what is described as a single device (or member, the same applies below) in the present specification (including what is depicted as a single device in the drawings) may be realized by a plurality of devices. Conversely, what is described as a plurality of devices in the present specification (including what is depicted as a plurality of devices in the drawings) may be realized by a single device. Alternatively, some or all of the means or functions included in a certain device may be included in another device. Furthermore, the “system” may include one device or may include two or more devices.

In addition, not all the matters described in the present specification are essential requirements. In particular, matters described in the present specification but not described in the claims can be regarded as optionally additional matters.

In addition, unless otherwise specified, the term “means” in the present specification and claims means refers to hardware itself (or a function realized by hardware), and does not include a human (or a human mental activity).

It should be noted that the applicant of the present invention is merely aware of the invention disclosed in the document in the “Prior Art Document” section of the present specification, and the present invention is not necessarily intended to solve the problem in the invention disclosed in the document. The problem to be solved by the present invention should be recognized in consideration of the entire specification. For example, in a case where it is described in the present specification that a specific effect is achieved by a particular configuration, it can be said that a problem that is the opposite of the specific effect is solved. However, such a particular configuration is not necessarily an essential requirement.

### DESCRIPTION OF REFERENCE NUMERALS

100 Substrate processing apparatus
1 Housing
2 Load port
3, 3a to 3d Substrate polishing apparatus
4, 4a, 4b Substrate cleaning apparatus
5 Substrate drying apparatus
6, 6a to 6c Substrate transport apparatus
42a to 42d Roller
43a, 43b Rotation driver
44a, 44b Substrate cleaning tool
45 Cleaning liquid supply nozzle
46 Housing
50 Rotation speed calculation apparatus
51, 52, 61a to 61d Vibration sensor
53, 62 Rotation speed calculator

What is claimed is:

1. A rotation speed calculation apparatus comprising:
a first vibration sensor configured to detect a vibration generated when a notch in a peripheral edge portion of a substrate to be cleaned hits a roller holding the peripheral edge portion of the substrate when the substrate is rotated by driving the roller to rotate;
a second vibration sensor configured to detect a vibration of a housing defining a space in which the substrate is cleaned; and
a rotation speed calculator configured to calculate a rotation speed of the substrate based on the vibration detected by the first vibration sensor and the vibration detected by the second vibration sensor.

2. The rotation speed calculation apparatus according to claim 1, wherein the rotation speed calculator calculates the rotation speed of the substrate based on the vibrations detected by the first vibration sensor and the second vibration sensor so as to cancel the vibration of the housing.

3. The rotation speed calculation apparatus according to claim 1, wherein the rotation speed calculator calculates the rotation speed of the substrate based on a value obtained by subtracting the vibration detected by the second vibration sensor from the vibration detected by the first vibration sensor.

4. A rotation speed calculation apparatus comprising:
two or more vibration sensors configured to detect vibrations generated when a notch in a peripheral edge portion of a substrate to be cleaned hits a plurality of rollers holding the peripheral edge portion of the substrate, respectively, when the substrate is rotated by driving the rollers to rotate, each of the two or more vibration sensors being provided to correspond to each of two or more of the plurality of rollers; and
a rotation speed calculator configured to calculate a rotation speed of the substrate based on the vibrations detected by the two or more vibration sensors.

5. The rotation speed calculation apparatus according to claim 4, wherein the rotation speed calculator calculates the rotation speed of the substrate based on a value obtained by adding the vibrations detected by the two or more vibration sensors.

6. The rotation speed calculation apparatus according to claim 4, wherein a first number of rollers is equal to a second number of vibration sensors, and
each of the two or more vibration sensors is provided to correspond to each of the plurality of rollers.

7. A rotation speed calculation apparatus comprising:
a first sound sensor configured to detect a sound generated when a notch in a peripheral edge portion of a substrate to be cleaned hits a roller holding the peripheral edge portion of the substrate when the substrate is rotated by driving the roller to rotate;
a second sound sensor configured to detect a sound generated from a housing defining a space in which the substrate is cleaned; and
a rotation speed calculator configured to calculate a rotation speed of the substrate based on the sound detected by the first sound sensor and the sound detected by the second sound sensor.

8. A rotation speed calculation apparatus comprising:
two or more sound sensors configured to detect sounds generated when a notch in a peripheral edge portion of a substrate to be cleaned hits a plurality of rollers holding the peripheral edge portion of the substrate, respectively, when the substrate is rotated by driving the rollers to rotate, each of the two or more sound sensors being provided to correspond to each of two or more of the plurality of rollers; and
a rotation speed calculator configured to calculate a rotation speed of the substrate based on the sounds detected by the two or more sound sensors.

9. A substrate cleaning apparatus comprising:
a roller;
a rotation driver configured to rotate a substrate to be cleaned by driving the roller to rotate;
a substrate cleaning tool configured to perform cleaning in contact with the substrate that is being rotated; and
the rotation speed calculation apparatus according to claim 1.

10. A substrate processing apparatus comprising:
a substrate polishing apparatus configured to polish a substrate; and
the substrate cleaning apparatus according to claim 9 configured to clean the polished substrate.
